(19) United States
(12) Patent Application Publication
(10) Pub. No.: US 2024/0413800 A1
(43) Pub. Date: Dec. 12, 2024

(54) CURRENT LIMIT FOR CHARGE PUMP BOOST DRIVEN CLASS D AUDIO AMPLIFIER

(71) Applicant: Texas Instruments Incorporated, Dallas, TX (US)

(72) Inventors: Shailendra Kumar Baranwal, Murphy, TX (US); Yogesh Kumar Ramadass, San Jose, CA (US); Yinglai Xia, Plano, TX (US)

(21) Appl. No.: 18/808,183

(22) Filed: Aug. 19, 2024

Related U.S. Application Data
(63) Continuation of application No. 17/461,495, filed on Aug. 30, 2021, now Pat. No. 12,095,429.

(51) Int. Cl. H03F 3/217; H03F 1/02; H04R 3/00

(52) U.S. Cl. CPC H03F 3/2171; H03F 1/0205; H04R 3/00; H03F 2200/03

(57) ABSTRACT

Described embodiments include an audio amplifier circuit that includes a first amplifier having a differential first amplifier input adapted to be coupled to an audio input source, a multiplexer having first and second mux inputs, a control input and a mux output. The first mux input is coupled to the differential amplifier output. There is a signal generator having a generator input coupled to the mux output. There is also a driver circuit having a driver circuit input and a driver circuit output, the driver circuit input coupled to the generator output, and a second amplifier having a first error input coupled to a current sense terminal that is configured to provide a voltage proportional to a current supplied from a power supply terminal, and a second error input coupled to a current limit terminal configured to provide a reference voltage proportional to a current limit value.

### CROSS-REFERENCE TO RELATED APPLICATIONS

This application is a continuation of U.S. patent application Ser. No. 17/461,495, filed Aug. 30, 2021, which is incorporated by reference herein its entirety.

### BACKGROUND

This description relates to class D audio amplifiers, and in particular, current limiting in class D audio amplifiers. Limiting the current drawn by an audio amplifier is particularly important in portable battery-powered systems because it directly impacts the operational time of the battery before requiring recharging.

A class-D amplifier is an electronic amplifier in which the amplifying devices operate as electronic switches, and not as linear gain devices as may be the case in other types of amplifiers. Class D amplifiers operate by rapidly switching back and forth between the positive and negative supply rails, or between the positive supply rail and ground. The switches in a class D amplifier are controlled by a modulator output using pulse width, pulse density, or a similar technique to encode the audio input into a pulse train.

In a pulse-width modulated amplifier, the duty cycle or on-time of the transistors is directly proportional to the power delivered to the load. The power delivered to the load is proportional to the battery current. So, battery current can be controlled by controlling the duty cycle of the pulse-width modulator.

### SUMMARY

In a first described embodiment, an audio amplifier circuit includes a first amplifier having a differential first amplifier input and a differential first amplifier output. The differential first amplifier input adapted to be coupled to an audio input source. The first described embodiment also presents a multiplexer having first and second mux inputs, a control input and a mux output. The first mux input is coupled to the differential amplifier output. There is a signal generator having a generator input and a generator output, and the generator input is coupled to the mux output.

The first described embodiment also includes a driver circuit having a driver circuit input and a driver circuit output, the driver circuit input being coupled to the generator output, and a second amplifier having first and second error inputs and an error output, the first error input coupled to a current sense terminal configured to provide a voltage proportional to a power supply current, the second error input coupled to a current limit terminal that is configured to provide a reference voltage proportional to a current limit value.

The second described embodiment presents a speaker system that includes a first amplifier having a differential first amplifier input and a differential first amplifier output, the differential first amplifier input adapted to be coupled to an audio input source. There is a multiplexer having first and second mux inputs, a control input and a mux output. The first mux input is coupled to the differential first amplifier output.

The second embodiment also includes a signal generator having a generator input and a generator output, the generator input coupled to the mux output, and a driver circuit having a driver circuit input and a driver circuit output. The driver circuit input is coupled to the generator output, and the driver circuit output is differential and coupled to first and second speaker drive terminals. There is a speaker having first and second speaker terminals coupled, respectively, to the first and second speaker drive terminals, and a second amplifier having first and second error inputs and an error output, the first error input coupled to a current sense terminal configured to provide a voltage proportional to a current supplied from the power source, the second error input coupled to a current limit terminal configured to provide a reference voltage proportional to a current limit value.

The third described embodiment presents an audio amplifier circuit that includes a first amplifier having a differential first amplifier input and a differential first amplifier output, the differential first amplifier input adapted to be coupled to an audio input source, a multiplexer having first and second mux inputs, a control input and a mux output, the first mux input coupled to the differential first amplifier output. There is a signal generator having a generator input and a generator output, the generator input coupled to the mux output, and a driver circuit having a driver circuit input and a driver circuit output, the driver circuit input is coupled to the generator output, and the driver circuit output is differential and coupled to first and second speaker drive terminals.

The third embodiment includes a second amplifier having first and second error inputs and an error output, the first error input coupled to a current sense terminal configured to provide a voltage proportional to a power supply current, the second error input coupled to a current limit terminal configured to provide a reference voltage proportional to a current limit value. The multiplexer selects the first mux input when the power supply current is less than the current limit value, and selects the second mux input when the power supply current is greater than the current limit value.

### BRIEF DESCRIPTION OF THE DRAWINGS

FIG. 1 shows an example output stage for a class D audio amplifier with an inductor-based boost converter.

FIG. 2 shows an example output stage for a class D audio amplifier with a capacitor-based boost converter.

FIG. 3 shows an example circuit model for a class D audio amplifier with a capacitor-based boost converter.

FIG. 4 shows a class D audio amplifier circuit having an improved current limit.

FIG. 5 shows an example implementation of a multiplexer for a class D audio amplifier circuit.

FIG. 6 shows an example implementation of a circuit for generating error voltages for controlling a multiplexer for a class D audio amplifier circuit.

### DETAILED DESCRIPTION

In this description, the same reference numbers depict the same or similar (by function and/or structure) features. The drawings are not necessarily drawn to scale.

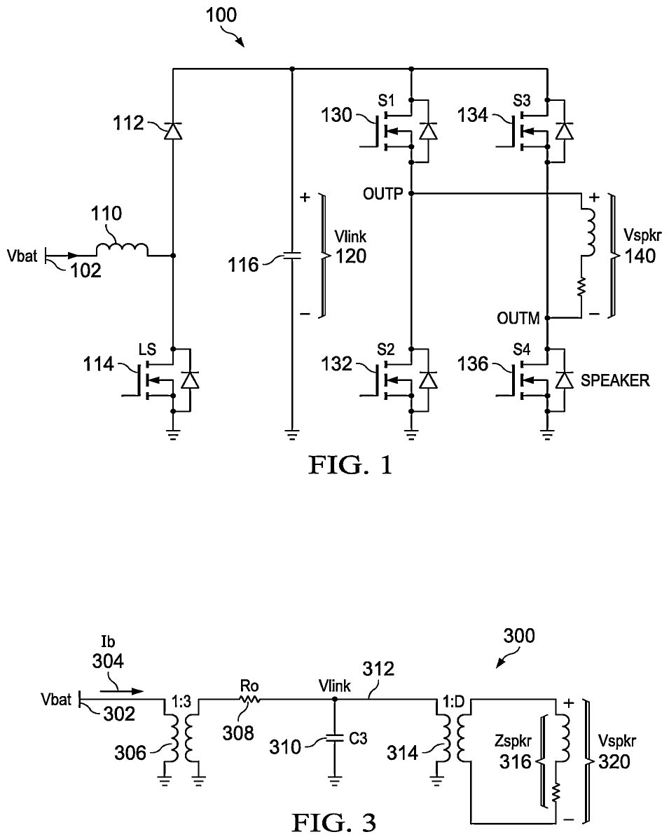

FIG. 1 shows an example output stage 100 for a class D audio amplifier with an inductor-based boost converter. V_{BAT} 102 is the supply voltage for the speaker driver. The supply voltage source could be a battery or any other DC power source. The inductor-based boost converter includes an inductor 110, a diode 112, a switch 114 and a capacitor 116. The inductor 110 receives the supply voltage V_{BAT} 102 at a first terminal. The second terminal of inductor 110 is coupled to the anode of diode 112 and to a first current terminal of switch 114. The second current terminal of switch 114 is coupled to ground. In at least one example, switch 114 is a transistor. Capacitor 116 is coupled between the cathode of diode 112 and ground. The voltage across capacitor 116 supplies the upper rail voltage V_{LINK} 120 to drive transistors 130 and 134. The boost converter boosts the supply voltage V_{BAT} 102 to a higher voltage at V_{LINK} 120 (e.g. from 3V to 10 V).

When the switch 114 is turned on, current flows from V_{BAT} 102 to ground through the inductor 110 causing the inductor current to rise. When the switch 114 is turned off, the current that has built up in inductor 110 flows through the diode 112 and charges up capacitor 116, thus increasing V_{LINK} 120. The inductor current decreases as the capacitor 116 is being charged. The inductor 110 acts as a current source to charge capacitor 116.

In at least one example, there is a feedback loop with an op amp (not shown) having a first op amp input coupled to the cathode of diode 112 sampling the voltage at V_{LINK} 120, a second op amp input coupled to a reference voltage source, and an output coupled to the control terminal of switch 114. The feedback loop regulates the output at V_{LINK} 120 to the desired voltage (e.g. 10V) by controlling the on time of switch 114.

Transistors 130 and 132 are connected in series between V_{LINK} 120 and ground. The connection point of transistors 130 and 132 is labeled OUTP. Transistor 134 and 136 are also connected in series between V_{LINK} 120 and ground. The connection point between transistors 134 and 136 is labeled OUTM. A speaker is connected between OUTP and OUTM. The differential voltage between OUTP and OUTM, which drives the speaker, is Vₛₚₖᵣ 140.

OUTP and OUTM are switching between V_{LINK} 120 and ground. The differential voltage between OUTP and OUTM is provided as a square wave, but will be seen as a sine wave because the speaker acts as a lowpass filter on the OUTP and OUTM waveforms. If the speaker volume is increased, then the voltage across the speaker will increase. As the voltage across the speaker increases, the battery current from V_{BAT} 102 will increase linearly with it. One method to limit the current being supplied by V_{BAT} 102 is to sense the current through inductor 110 and turn off switch 114 when the current exceeds a current limit. This is not an ideal method for implementing battery current limit protection because inductors are large in comparison to other components, increasing the board space and component headroom required to fit the inductors. The requirement for added board space for the inductor makes the solution of FIG. 1 less desirable.

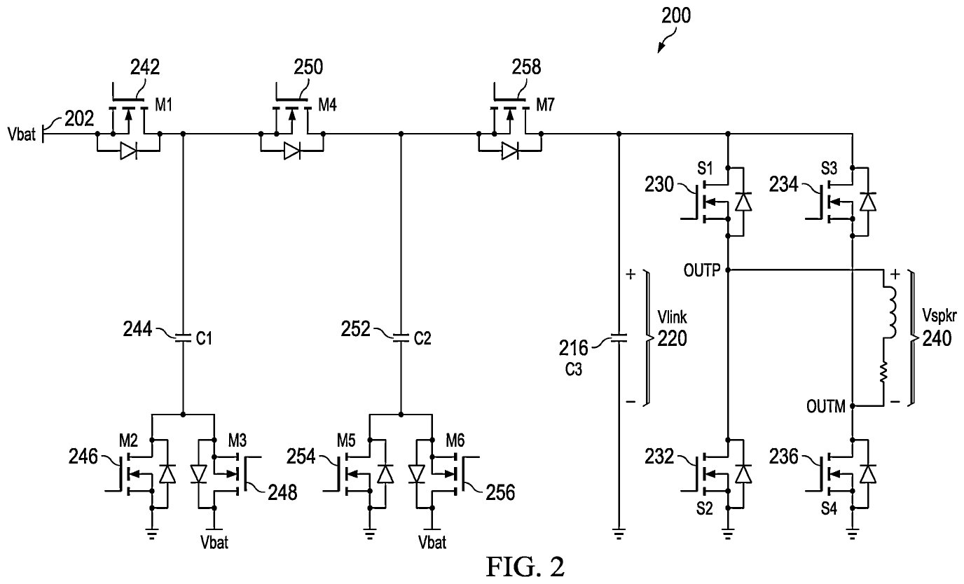

FIG. 2 shows an example output stage 200 for a class D audio amplifier with a capacitor-based boost converter. V_{BAT} 202 is the supply voltage for the speaker driver. The supply voltage source could be a battery or any other DC power source. The capacitor-based boost converter shown has two stages, but more or less stages can be used in other examples. Each boost converter stage comprises a capacitor and two transistors, and each boost converter stage adds an amount V_{BAT} to the voltage at V_{BAT}. So, having two boost converter stages results in a voltage equal to 3*V_{BAT} (or V_{BAT}+V_{BAT}+V_{BAT}) at V_{LINK} 220. Transistors 242, 250 and 258 are switched on and off to sum the voltages and create the charge pump.

Transistors 246 and 248 are coupled in series between V_{BAT} 202 and ground. Capacitor 244 has a first capacitor terminal connected to the connection point of transistors 246 and 248 and a second capacitor terminal connected to an output current terminal of transistor 242. Transistor 242 has an input current terminal receiving voltage V_{BAT} 202. Transistors 242 and 246 are turned on while transistor 248 is turned off, charging capacitor 244 to a voltage of V_{BAT} 202. The voltage across capacitor 244 is at V_{BAT}, and that capacitor voltage is added to the voltage at the output current terminal of transistor 242, which is also at a voltage of V_{BAT} 202, by turning on switch 248. The result is that the voltage at the input current terminal of transistor 250 is 2*V_{BAT} (or V_{BAT}+V_{BAT}).

Similarly, transistors 254 and 256 are coupled in series between V_{BAT} 202 and ground. Capacitor 252 has a first terminal connected between the connection point of transistors 254 and 256 and a second terminal connected to the output current terminal of transistor 250. Transistors 250 and 254 are turned on while transistor 256 is turned off, charging capacitor 252 to a voltage of 2*V_{BAT}. The voltage across capacitor 252 is 2*V_{BAT}, and that voltage is added to the voltage of V_{BAT} 202 by turning on switch 256. The result is that the voltage at the input current terminal of transistor 258 is 3*V_{BAT} (or V_{BAT}+V_{BAT}+V_{BAT}).

Transistors 242, 250 and 258 turn on and turn off to create a charge pump, increasing the voltage V_{LINK} 220 across capacitor 216. In example 200, V_{LINK}=3*V_{BAT} because there are 2 charge pump stages and each charge pump stage increases the voltage V_{LINK} 220 by the amount V_{BAT}. However, additional stages may be added if a higher ratio of V_{LINK} to V_{BAT} is desired.

Transistors 230 and 232 are connected in series between V_{LINK} 220 and ground. The connection point of transistors 230 and 232 is labeled OUTP. Transistors 234 and 236 are also connected in series between V_{LINK} 220 and ground. The connection point between transistors 234 and 236 is labeled OUTM. A speaker is connected between OUTP and OUTM. The differential voltage between OUTP and OUTM, which drives the speaker, is Vₛₚₖᵣ 240.

OUTP and OUTM are switching between V_{LINK} 220 and ground. The differential voltage between OUTP and OUTM is provided to the speaker as a square wave, but will be seen as a sine wave because the speaker acts as a lowpass filter on the voltage waveform. If the speaker volume is increased, the voltage across the speaker will increase. As the voltage across the speaker increases, the battery current supplied by V_{BAT} 202 will increase linearly with it.

FIG. 3 shows an example circuit model 300 for a class D audio amplifier with a capacitor-based boost converter. Circuit model 300 is an aid to understand the mathematical relationship between the speaker voltage Vₛₚₖᵣ 240 and the current supplied from V_{BAT} 202. However, the circuit elements shown in circuit model 300 are not necessarily illustrative of the actual circuit elements in the embodiment. The battery voltage is represented as V_{BAT} 302. The current supplied by the battery is represented as I_{B} 304. Transformer 306 represents a charge pump. The transformer 306 is shown as having an input-to-output voltage ratio of 1:3, representing the voltage boosting of V_{BAT} 302 to V_{LINK} 312. Other examples may have a different boosting ratio of V_{BAT} to V_{LINK}.

Ro 308 represents the impedance of the charge pump transistors (transistors 242, 250 and 258 in FIG. 2). The voltage across capacitor 310 is V_{LINK} 312. A speaker is modeled as having an impedance Zₛₚₖᵣ 316, which could be a combination of a resistance and an inductance. The voltage provided to the speaker is modeled as Vₛₚₖᵣ 320. Transformer 314 represents drive transistor S1-S4 (transistors 230, 232, 234 and 236 in FIG. 2). The transformer 314 is shown as having an input to output voltage ratio of 1:D representing the voltage ratio of V_{LINK} 312 to Vₛₚₖᵣ 320. D represents the duty cycle or on-time of the high side transistors (transistors 230 and 234 in FIG. 2).

If the speaker is demanding a volume that requires current I through the speaker, then the current Ib 304 required from Vbat 302 will be equal to 3*I because the voltage Vspkr 320 is equal to 3*Vbat. To maintain constant power (power in=power out), the current will be reduced by a factor of N if the voltage is increased by a factor of N. While there is not an actual transformer in the circuit, the same principle of conservation of energy applies with a class D amplifier using a charge pump.

For example, if a system requirement is that no more than 2 A of current may be drawn from the battery, the speaker current must not exceed ⅔ A if V_{LINK} is equal to 3*V_{bat}. If the speaker draws more than ⅔ A in this example, the battery current limit will be exceeded. One potential method to limit the battery current drawn is to increase the impedance of the charge pump transistors Ro 308 so that the voltage drop across Ro 308 is higher. A higher voltage drop across Ro 308 means that V_{LINK} 312 will be lower. If V_{LINK} 312 is lower, then Vspkr 320 will be lower, thus making the speaker current higher to maintain a constant power. So, an increase in the impedance of the charge pump transistors Ro 308 leads to a lower current draw from the battery. However, there is no direct control over Ro 308, and other methods, such as lowering the charge pump switching frequency to control Ro, result in thermal power loss, which lowers the power efficiency. Therefore, increasing the impedance of the charge pump transistors Ro 308 is not an attractive solution for limiting battery current.

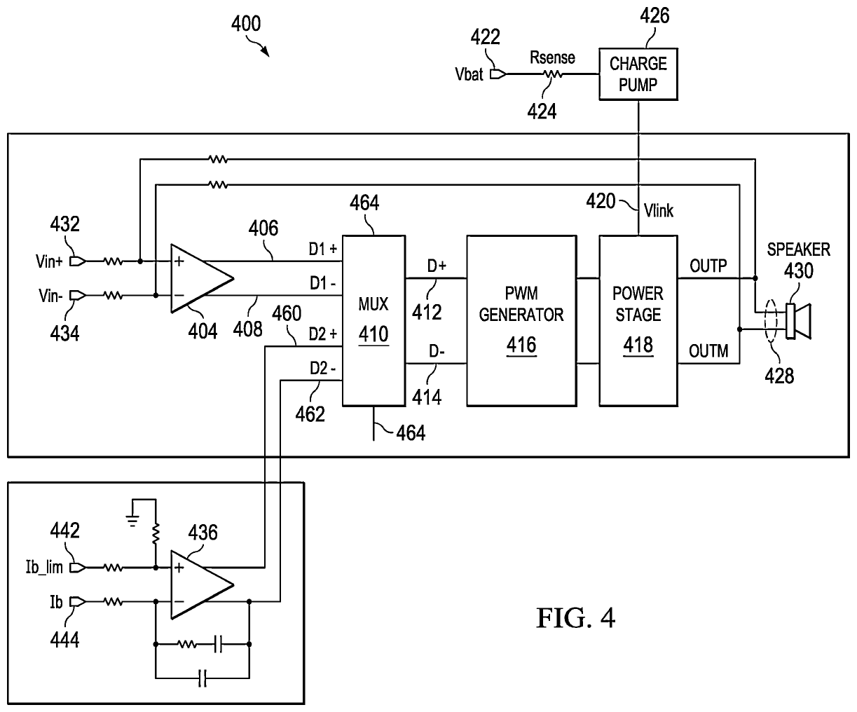

FIG. 4 shows a class D audio amplifier circuit 400 with an improved current limit. The differential audio signal V_{IN+} 432 and V_{IN-} 434 is coupled to the input terminals of amplifier 404. The output of amplifier 404 is differential signal D1+ 406 and D1− 408, which are coupled to the first input terminals of analog multiplexer 410. The output of multiplexer 410 is a differential signal D+ 412 and D− 414, which are provided to the input terminals of pulse-width-modulation (PWM) generator 416. The differential output of PWM generator 416 is coupled to the input of power stage 418. In some examples, power stage 418 includes power transistors capable of providing enough current to drive a speaker 430. Power stage 418 is supplied by the output of charge pump 426 which provides voltage V_{LINK} 420 to power stage 418.

A first input terminal of amplifier 436 is coupled to a terminal providing a signal proportional to the battery current Ib 444. A second input terminal of amplifier 436 is coupled to a terminal providing a current limit reference voltage Ib_lim 442. The outputs of amplifier 436, differential signal D₂+ 460 and D₂− 462, are coupled to the second input terminals of multiplexer 410. The output of multiplexer 410 is differential signal D+ 412 and D− 414, which is selected by multiplexer 410 to be either D₁+ 406 and D₁− 408 or D₂+ 460 and D₂− 462.

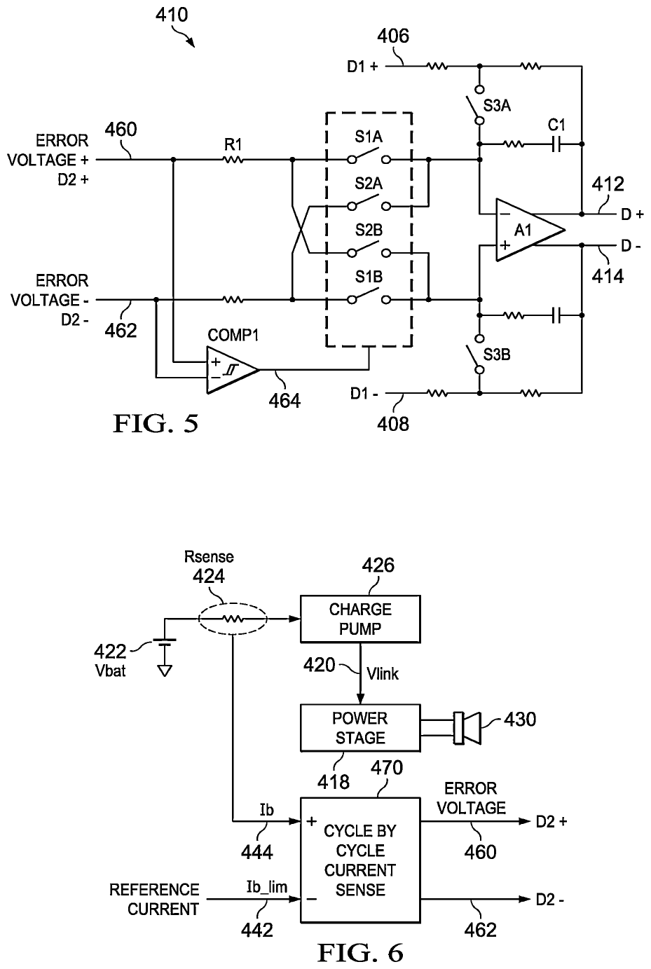

FIG. 5 shows an example implementation of multiplexer 410. Error voltage outputs D₂+ 460 and D₂− 462, respectively, are coupled to the first and second input terminals of comparator COMP1. The output 464 of comparator COMP1 controls the position of switches S1 A/B, S2 A/B and S3 A/B. When the circuit is in normal operation and the battery current is within the battery current limit, switch S3 A/B is closed and switches S1 A/B and S2 A/B are open. If the supplied battery current exceeds the battery current limit, switch S3 A/B is opened and switches S1 A/B and S2 A/B close.

FIG. 6 shows an example implementation of a circuit for generating error voltage outputs D₂+ 460 and D₂− 462. Voltage source V_{bat} 422 is coupled to the input of charge pump 426 through current sensing resistor Rₛₑₙₛₑ 424. The output of charge pump 426 is V_{LINK} 420, which provides power to the amplifier power stage 418 to drive the speaker 430. The current drawn from the battery Ib 444 is sensed by Rₛₑₙₛₑ 424. Battery current Ib 444 is provided as a first input to current sense circuit 470. The second input of current sense circuit 470 is Ib_lim 442, which is a reference voltage that sets the battery current limit value. Current sense circuit 470 provides at its output an error voltage representing the difference between the battery current being supplied and the battery current limit. The output of current sense circuit 470 is D₂+ 460 and D₂− 462, which are coupled to the first and second inputs, respectively, of COMP1 464.

If the battery current Ib 444 is lower than the battery current limit Ib_lim 442, the error voltage D₂+ 460 and D₂− 462 will be positive, making the output of COMP1 464 high. When the output of COMP1 464 is high, switch S3 will be closed and switches S1 and S2 will be open. With switch S3 closed and switches S1 and S2 open, the input to amplifier A1 will be coupled to D₁+ 406 and D₁− 408.

If the battery current Ib 444 is higher than the battery current limit Ib_lim 442, the error voltage D₂+ 460 and D₂− 462 will be negative, making the output of COMP1 464 low. When the output of COMP1 464 is low, switch S3 will be open and switches S1 and S2 will be closed. With switch S3 open and switches S1 and S2 closed, the input to amplifier A1 will be coupled to D₂+ 460 and D₂− 462.

Amplifier A1, which is configured as an integrator in at least one example, has a differential output D+ 412 and D− 414, which corresponds to a duty cycle D for the PWM signal that will control how the speaker 430 is driven, and thus how much current is required from the battery. The input of PWM generator 416 is coupled to the output of MUX 410. The output of PWM generator 416 is coupled to the input of power stage 418, which is powered by voltage V_{LINK} 420. Voltage V_{LINK} 420 is generated by charge pump 426 which draws battery current Ib 444 to drive speaker 430. The output of power stage 418 is OUTP and OUTM, which drives speaker 430, and are also coupled to the input terminals of amplifier 404.

The battery current Ib 444 is proportional to the current through V_{LINK} 420. The current through V_{LINK} 420 is proportional to the speaker current, which is proportional to the voltage across the speaker, OUTP and OUTM. Therefore, to limit the input battery current, the voltage across the speaker must be limited, and this is done by controlling the duty cycle D, the output of mux 410, D+ 412 and D− 414.

As used herein, the terms “terminal”, “node”, “interconnection”, “lead” and “pin” are used interchangeably. Unless specifically stated to the contrary, these terms are generally used to mean an interconnection between or a terminus of a device element, a circuit element, an integrated circuit, a device, or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, even if operations are described in a particular order, some operations may be optional, and the operations are not necessarily required to be performed in that particular order to achieve desirable results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

What is claimed is:

1. A circuit comprising:
a first amplifier having a first amplifier input and a first amplifier output;
a multiplexer having first and second mux inputs, a control input and a mux output, wherein the first mux input is coupled to the first amplifier output;
a drive circuit having a drive input and a drive output, wherein the drive input is coupled to the mux output; and
a second amplifier having second and third amplifier inputs and a second amplifier output, wherein the third amplifier input is coupled to a current sense terminal configured to provide a voltage proportional to a supply current supplied through a power source terminal, the third amplifier input is coupled to a reference voltage terminal, and the second amplifier output is coupled to the second mux input.

2. The circuit of claim 1, additionally comprising a charge pump having a charge pump input and a charge pump output, wherein the charge pump input is coupled to the power source terminal, and the charge pump output is coupled to a voltage source input of the drive circuit.

3. The circuit of claim 2, wherein the drive circuit includes first, second, third and fourth transistors.

4. The circuit of claim 3, wherein:
the first transistor has first and second current terminals, the first current terminal is coupled to the charge pump output, and the second current terminal is coupled to the drive output;
the second transistor has third and fourth current terminals, the third current terminal is coupled to the second current terminal, and the fourth current terminal is coupled to a ground terminal;
the third transistor has fifth and sixth current terminals, the fifth current terminal is coupled to the charge pump output, and the sixth current terminal is coupled to the drive output; and
the fourth transistor has seventh and eighth current terminals, the seventh current terminal is coupled to the sixth current terminal, and the eighth current terminal is coupled to the ground terminal.

5. The circuit of claim 1, wherein the multiplexer includes:
a first switch having a first switch input, a first switch output and a first switch control terminal, wherein the first switch input is coupled to the second amplifier output;
a second switch having a second switch input, a second switch output and a second switch control terminal, wherein the second switch input is coupled to the second amplifier output;
a third switch having a third switch input, a third switch output and a third switch control terminal, wherein the third switch input is coupled to the first amplifier output; and
a third amplifier having a fifth amplifier input and a third amplifier output, wherein the fifth amplifier input is coupled to the first, second and third switch outputs, and the third amplifier output is coupled to the mux output.

6. The circuit of claim 5, wherein the third amplifier is configured as an integrator.

7. The circuit of claim 5, including a comparator having first and second comparator inputs and a comparator output, wherein the first comparator input is coupled to the current sense terminal, the second comparator input is coupled to the reference voltage terminal, and the comparator output is coupled to the first, second and third switch control terminals.

8. The circuit of claim 7, wherein the first and second switches are closed and the third switch is open in response to the comparator output having a first logic state, and the first and second switches are open and the third switch is closed in response to the comparator output having a second logic state.

9. The circuit of claim 1, wherein the drive circuit includes a pulse-width-modulated (PWM) generator circuit.

10. The circuit of claim 1, wherein the drive output is coupled to a speaker.

11. The circuit of claim 2, wherein the charge pump is a capacitor-based charge pump.

12. A circuit comprising:
a first amplifier having a first amplifier input and a first amplifier output;
a multiplexer having first and second mux inputs, a control input and a mux output, wherein the first mux input is coupled to the first amplifier output;
a drive circuit having a drive input and a drive output, wherein the drive input is coupled to the mux output; and
a second amplifier having second and third amplifier inputs and a second amplifier output, wherein the second amplifier input is coupled to a current sense terminal that is configured to provide a voltage proportional to a power supply current, the third amplifier input is coupled to a current limit terminal that is configured to provide a reference voltage proportional to a current limit value;
wherein, the multiplexer selects the first mux input when the power supply current is less than the current limit value, and selects the second mux input when the power supply current is greater than the current limit value.

13. The circuit of claim 12, wherein the drive circuit includes a pulse-width-modulated (PWM) generator circuit.

14. The circuit of claim 13, wherein the PWM generator circuit provides a PWM signal having a duty cycle responsive to the mux output.

15. The circuit of claim 12, wherein the multiplexer includes:
a first switch having a first switch input, a first switch output and a first switch control terminal, wherein the first switch input is coupled to the second amplifier output;
a second switch having a second switch input, a second switch output and a second switch control terminal, wherein the second switch input is coupled to the second amplifier output;
a third switch having a third switch input, a third switch output and a third switch control terminal, wherein the third switch input is coupled to the first amplifier output; and
a third amplifier having a third amplifier input and a third amplifier output, wherein the third amplifier input is coupled to the first, second and third switch outputs, and the third amplifier output is coupled to the mux output.

16. The circuit of claim 15, wherein the third amplifier is configured as an integrator.
